(19) United States
(12) Patent Application Publication
(10) Pub. No.: US 2014/0248718 A1
(43) Pub. Date: Sep. 4, 2014

(54) PATTERNING OF MAGNETIC TUNNEL JUNCTION (MTJ) FILM STACKS

(71) Applicants: Jisoo Kim, Pleasanton, CA (US); Mang-mang Ling, Sunnyvale, CA (US); Khoi Doan, Milpitas, CA (US); Srinivas D. Nemani, Sunnyvale, CA (US)

(72) Inventors: Jisoo Kim, Pleasanton, CA (US); Mang-mang Ling, Sunnyvale, CA (US); Khoi Doan, Milpitas, CA (US); Srinivas D. Nemani, Sunnyvale, CA (US)

(21) Appl. No.: 14/183,257

(22) Filed: Feb. 18, 2014

Related U.S. Application Data
(60) Provisional application No. 61/772,149, filed on Mar. 4, 2013.

(51) Int. Cl. H01L 43/12

(52) U.S. Cl. CPC H01L 43/12
USPC 438/3

(57) ABSTRACT

Chemical modification of non-volatile magnetic random access memory (MRAM) magnetic tunnel junctions (MTJs) for film stack etching is described. In an example, a method of etching a MTJ film stack includes modifying one or more layers of the MTJ film stack with a phosphorous trifluoride (PF₃) source to provide modified regions of the MTJ film stack. The modified regions of the MTJ film stack are removed by a plasma etch process.

### CROSS-REFERENCE TO RELATED APPLICATIONS

This application claims the benefit of U.S. Provisional Application No. 61/772,149, filed on Mar. 4, 2013, the entire contents of which are hereby incorporated by reference herein.

### BACKGROUND

1) Field

Embodiments of the present invention pertain to the field of semiconductor processing and, in particular, to chemical modification of non-volatile magnetoresistive random access memory (MRAM) magnetic tunnel junctions (MTJs) for film stack etching.

2) Description of Related Art

Magnetoresistive random-access memory (MRAM) has recently attracted significant attention. With respect to patterning of film stacks for MRAM, physical sputtering rather than chemical etching has typically dominated the MRAM industry thus far. However, physical sputtering approaches have encountered significant issues, such as magnetic tunnel junction (MTJ) sidewall redeposition, because of the inclusion of non-volatile metallic and magnetic materials in MTJ film stacks. Such redeposition can lead to shorting between the layers below and above an included magnesium oxide (MgO) layer.

Thus, improvements are needed in the area of MTJ film stack patterning.

### SUMMARY

One or more embodiments are directed to chemical modification of non-volatile magnetoresistive random access memory (MRAM) magnetic tunnel junctions (MTJs) for film stack etching.

In an embodiment, a method of etching a MTJ film stack includes modifying one or more layers of the MTJ film stack with a phosphorous trifluoride (PF₃) source to provide modified regions of the MTJ film stack. The modified regions of the MTJ film stack are removed by a plasma etch process.

In an embodiment, a non-transitory machine-accessible storage medium has instructions stored thereon which cause a data processing system to perform a method of etching a magnetic tunnel junction (MTJ) film stack. The method involves modifying one or more layers of the MTJ film stack with a phosphorous trifluoride (PF₃) source to provide modified regions of the MTJ film stack. The modified regions of the MTJ film stack are removed by a plasma etch process.

In an embodiment, a method of etching a MTJ film stack involves providing a substrate having the MTJ film stack disposed thereon. The method also involves modifying one or more layers of the MTJ film stack with a phosphorous trifluoride (PF₃) source to provide modified regions of the MTJ film stack. The modifying involves introducing PF₃ gas into a processing chamber. The modifying also involves dissociating the PF₃ gas with RF energy in the processing chamber. The method also involves removing the modified regions of the MTJ film stack by a plasma etch process. The removing involves using an oxygen (O₂) based plasma process. The method also involves, subsequent using the O₂ based plasma process, cleaning the MTJ film stack with a chemical etch or dry clean process.

### BRIEF DESCRIPTION OF THE DRAWINGS

FIG. 1 illustrates cross-sectional views representing various processing operations in a method of patterning a magnetic tunnel junction (MTJ) film stack, in accordance with an embodiment of the present invention.

FIG. 2 includes (a) an illustration and (b) a photograph of a SPIN type Conforma ion implantation chamber, in accordance with an embodiment of the present invention.

FIG. 3 illustrates cross-sectional views representing various processing operations in a method of patterning a magnetic tunnel junction (MTJ) film stack, in accordance with another embodiment of the present invention.

FIG. 4 includes a TEM of an MTJ and corresponding EDX data analysis, in accordance with an embodiment of the present invention.

FIG. 5 illustrates a system in which a method of magnetic tunnel junction (MTJ) film stack etch processing can be performed, in accordance with an embodiment of the present invention.

FIG. 6 illustrates a block diagram of an exemplary computer system, in accordance with an embodiment of the present invention.

### DETAILED DESCRIPTION

Chemical modification of non-volatile magnetic random access memory (MRAM) magnetic tunnel junctions (MTJs) for film stack etching is described. In the following description, numerous specific details are set forth, such as specific plasma treatments and material stacks MTJ layers, in order to provide a thorough understanding of embodiments of the present invention. It will be apparent to one skilled in the art that embodiments of the present invention may be practiced without these specific details. In other instances, well-known aspects, such as photolithography patterning and development techniques for photoresist mask formation, are not described in detail in order to not unnecessarily obscure embodiments of the present invention. Furthermore, it is to be understood that the various embodiments shown in the Figures are illustrative representations and are not necessarily drawn to scale.

One or more embodiments described herein relate to chemical modification of non-volatile MRAM MTJ material by doping with phosphorous trifluoride (PF₃). For example, specific embodiments are directed to MRAM MTJ PF3 dry etching of conductor dielectric materials by chemical modification doping through ion implantation.

As described above, physical sputtering approaches have encountered significant issues, such as magnetic tunnel junction (MTJ) sidewall redeposition, because of the inclusion of non-volatile metallic and magnetic materials in MTJ film stacks. In accordance with an embodiment of the present invention, chemical etching of such MRAM materials is performed in order to address these issues. As an exemplary embodiment, PF₃ doping is performed in a first operation, followed by dry plasma etch using further dry cleaning to chemically etch the non-volatile metal (NVM) and MTJ stack in an MRAM device. This approach enables chemical etching of the metal and magnetic materials which is otherwise be significantly challenging.

More specifically, one or more embodiments implement an ion implantation operation that is otherwise conventionally used for semiconductor material doping purposes. The implantation operation involves use of high ion energy plasma to chemically dope and modify certain materials such as metal and magnetic materials in order to render chemically etchable materials. As such, embodiments herein aid in etching the metal and magnetic materials where previously no chemical etching method had proven successful. The implantation plus chemical etching processes described inn greater detail below can readily be used for NVM etching such as magnetic metal stack etching in a magnetic random access memory (MRAM) device.

To provide deeper context, a significant issue in the fabrication of MRAM devices is that certain types of metal and magnetic materials are not chemically etchable since such materials do not typically react with chemicals such as chemically active species generated from a plasma. So far, only physical etching using physical bombardment, e.g., ion milling, has proven possible and remains as the current solution. However, such physical bombardment approaches have characteristically slow etch rates and often lead to sidewall redeposition. Examples of materials at issue for such etching considerations include, but are not limited to, cobalt palladium (CoPd) or cobalt platinum (CoPt). One acute issue involves, in the case of NVM etching, difficult to control parameters such as the slope and critical dimension (CD) of the multi-junction (MTJ) stacking profile. These parameters can prove difficult to control since the physical sputtering process rather than chemical etching dominates the material removal. Therefore it is very challenging to chemically etch a side of MTJ in order to a achieve desired profile angle and CD when the device feature is being scaled down.

In addition to the above parameter issues, non-volatile etch byproducts such as the mixture of metal and magnetic materials can be deposited on the sidewall of an etched MTJ structure leading to a tapered profile. A tapered profile can hamper the separation of very small pitch patterns at the bottom of a MTJ structure. This can lead to shorting between the layers below and above so-called magnesium oxide (MgO) dielectric or filter layers. Without properly addressing these issues, the fabricated MRAM device can exhibit electrical failure. Embodiments of the present invention can provide solutions to such problems by rendering chemical etch processing possible following ion implantation treatment of a targeted metal and magnetic material stack for patterning.

In an overall embodiment, conventional ion implantation is used to first chemically modify a targeted metal material. The result is that the targeted material is changed from a conductor into dielectric material. A dry etch process is then applied using various process gases to eventually achieve chemical etch upon the targeted material. Therefore, embodiments described herein enable a chemical etch of the metal and magnetic materials which would be otherwise prove difficult. In an exemplary embodiment, a dopant gas such as phosphorus trifluoride (PF₃) is used under conditions of low pressure, low source power, and high bias power.

Therefore, in an embodiment, a high ion energy is used to chemically modify the side of an MTJ layer during plasma main etch, so that further dry clean process using, e.g., N₂/H₂ or NF₃ gases can further chemically etch and clean the side wall residue and therefore reduce the CD at an MgO layer. Adding dopant into the material can eventually enhance the chemical etch rate of the targeted material. Based on the scanning electron microscopy (SEM), transmission electron microscopy (TEM) and the Energy-dispersive X-ray spectroscopy (EDX) analysis, as described in greater detail below, the side of the MTJ stacking structure is changed into a void after a duration of exposure to a N₂/H₂ or NF₃ dry clean process. This result indicates the effect of the ion implantation treatment as described above. Such a void is normally seen after longer timed etch, possibly due to wafer heating. Thus, in a specific embodiment, wafer heating can also be used, in addition to implantation, as an important factor to enable dry etching of such film stacks.

Advantages of embodiment of the present invention can include, but are not limited to, the use of high ion energy implantation treatment to chemically modify and therefore render possible the chemical etch of certain metal and magnetic materials such as MRAM's MTJ stack materials. The mechanism is that the MTJ side is altered from being a conductor to a dielectric materials by ion implantation so that further plasma dry etch can remove portions thereof and create voids around the MTJ stack. Thus, another advantage includes the possibility of CD shrink by using ion implantation treatment. Another advantage can include the result of altering of the side of the material stack from conductive to dielectric which can prevent shorting between the layers below and above the MgO layer, which is essential to the MRAM device operation.

The results achieved by implementing embodiments of the present invention are that the ion implantation with high ion energy can chemically modify and dope the targeting metal and magnetic materials so that subsequent chemical etch of MTJ using various process gas is made possible. Embodiments can provide MRAM sidewall cleaning approaches for the profile, a more vertical feature profile, control of the CD at the MgO layer, etc. Electrical shorting near MgO layer would also be avoided by converting metal and magnetic materials at sidewall into dielectric materials.

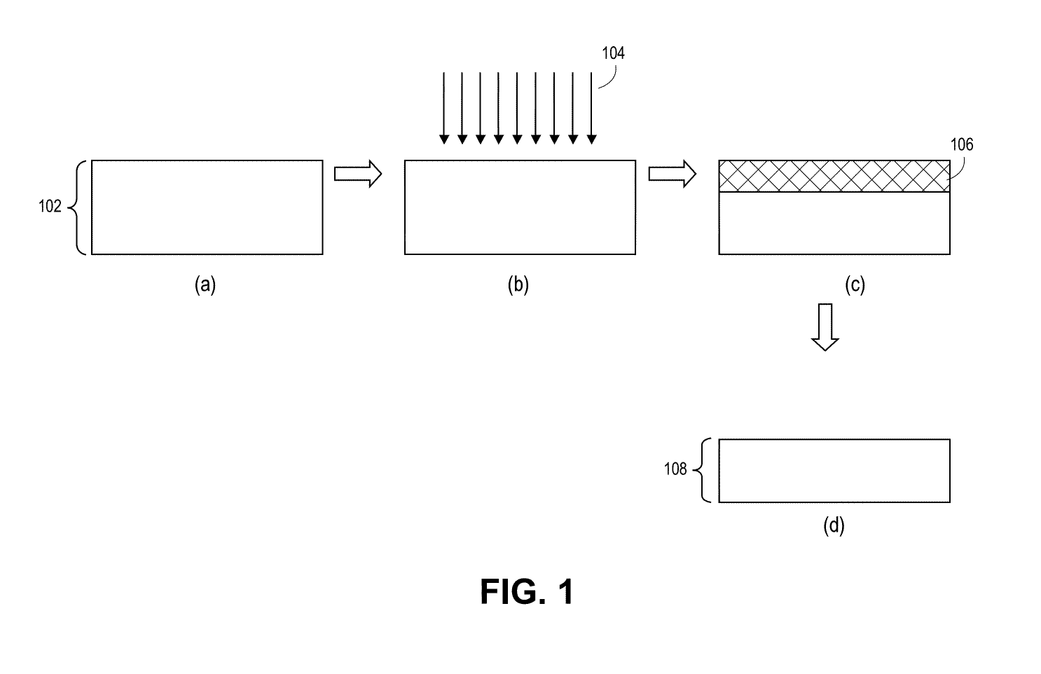

FIG. 1 illustrates cross-sectional views representing various processing operations in a method of patterning a magnetic tunnel junction (MTJ) film stack, in accordance with an embodiment of the present invention. Referring to FIG. 1, in (a) a metal and magnetic MTJ material stack 102 is provided; in (b) a high ion energy implantation process 104 is performed, e.g., a PF₃ treatment process; in (c) exposed metal and magnetic materials are doped, chemically doped and/or modified to dielectric materials, such as converted portion 106; and in (d) the modified metal and magnetic materials are removed by a chemical etch and, more particularly, a dry etch to provide etched film 108.

More generally, FIG. 1 shows the overall principle and operation mechanism of PF₃ doping and subsequent chemical etch. In one embodiment, the PF₃ gas is dissociated by the RF energy supplied into the processing chamber, forming fluorine active species and phosphorous active species. The fluorine active species slightly etch the surface of the exposed ferromagnetic layer while incorporating the phosphorous species into the surface ferromagnetic layer to modify the film properties. The implanted phosphorous elements may alter atom arrangement and distribution formed in the unmasked region, converting the exposed area to have film properties that may be easily attacked and removed by the etchant during the subsequent processing steps.

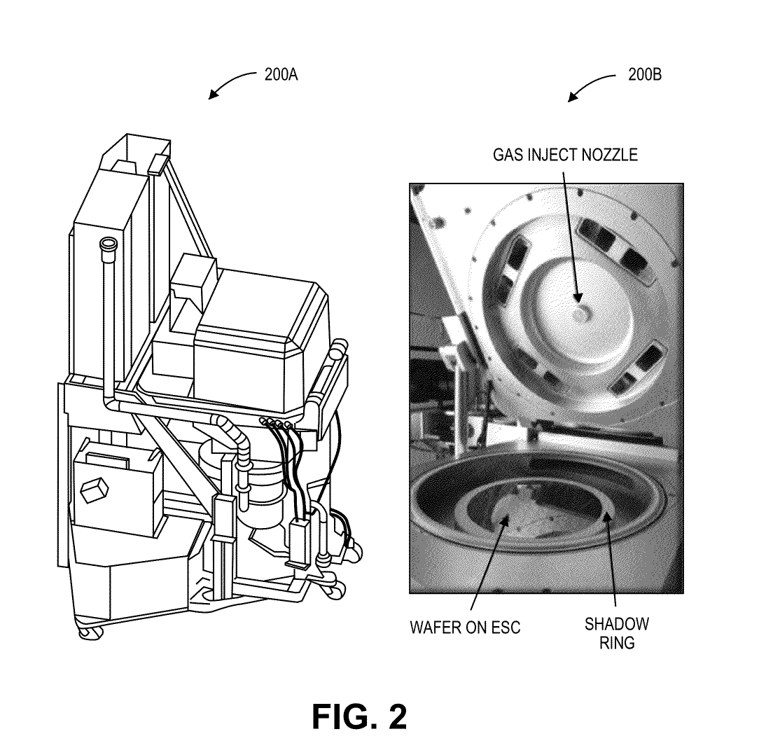

FIG. 2 includes (a) an illustration 200A and (b) a photograph 200B of a SPIN type Conforma ion implantation chamber, in accordance with an embodiment of the present invention. It is understood that the phosphorous elements supplied in the gas mixture during the plasma immersion ion implantation process may react with the Co, Pt or Pd elements in a ferromagnetic CoPt or CoPd MTJ layer to form complex compounds of phosphine to evaporate while Co phosphine is changed to liquid-like metal formed meniscus shape and then changed to solid metal immediately after etching. The phosphorous reacting with side of MTJ stack and then providing liquid-like metal again and then generating voids during volume shrinking in phase change to solid. The by-products may be easily attacked so as to react with the etchants subsequently supplied to facilitate removal of the MTJ materials.

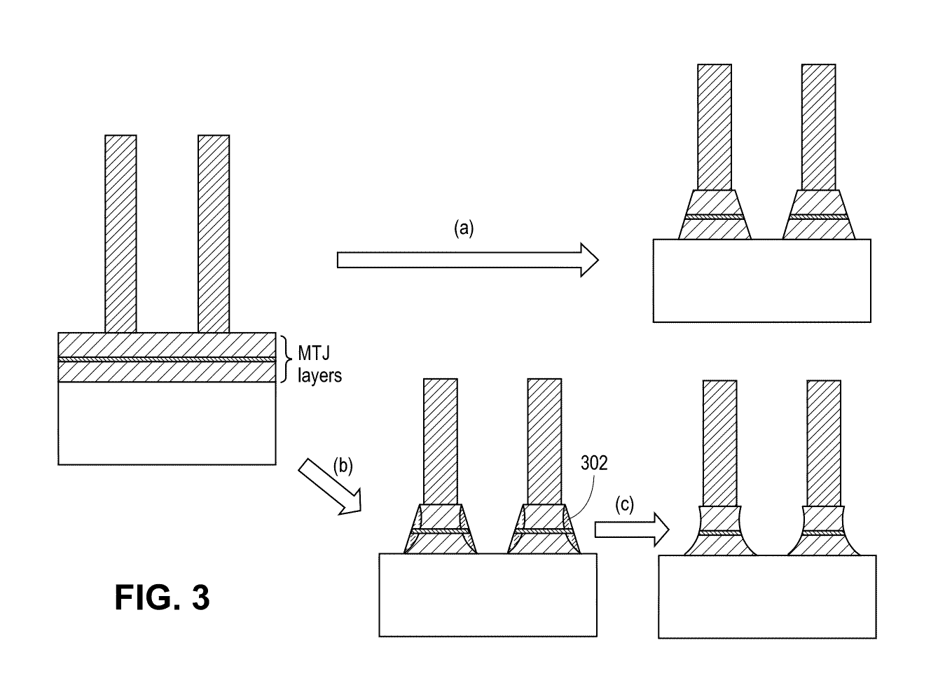

FIG. 3 illustrates cross-sectional views representing various processing operations in a method of patterning a magnetic tunnel junction (MTJ) film stack, in accordance with another embodiment of the present invention. More particularly, FIG. 3 illustrates the application of the chamber of FIG. 2 in MRAM MTJ etch processing. As a comparison, pathway (a) of FIG. 3 illustrates a process without ion implantation treatment. Alternatively, in an embodiment, pathway (b) of FIG. 3 shows ion implantation treatment using high ion energy. The voids 302 are generated due to chemical modification of MTJ stack sidewalls by ion implantation treatment with high ion energy. Subsequently, pathway (c) of FIG. 3 illustrates post dry etch to chemically etch and remove the metal and magnetic materials of MTJ sidewall.

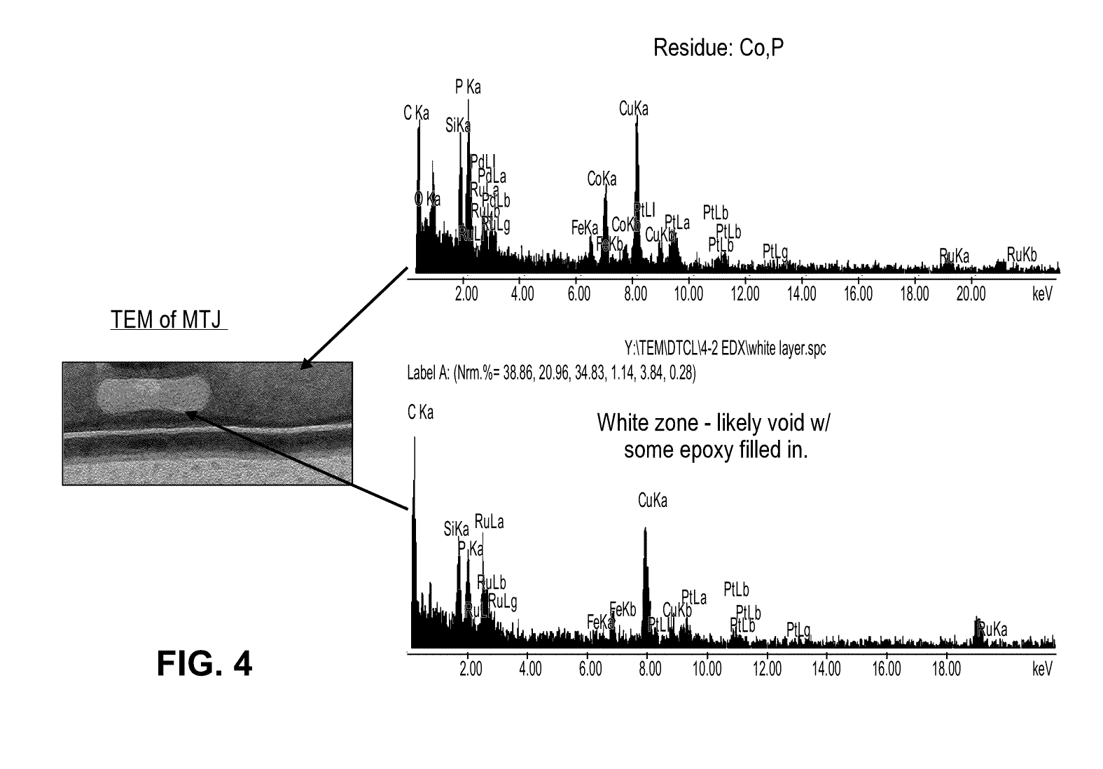

FIG. 4 includes a TEM of an MTJ and corresponding EDX data analysis, in accordance with an embodiment of the present invention. FIG. 4 reveals that Co—P fromed from PF₃ byproducts converts to PO after an O₂ plasma treatment and can then can be chemically etched/removed by a further dry clean process. The voids are generated due to chemical modification of MTJ stack side by ion implantation treatment. Further post dry etch can chemically etch away the materials of MTJ sidewall.

Overall, in order to realize chemical etch of non-volatile MRAM materials in order to eliminate sidewall residue and avoid shorting, a first operation involves use of conventional ion implantation approaches, e.g., using a SPIN type Conforma chamber to chemically modify the targeted metal material. For example, a metal material is changed from conductor into dielectric material. Dopant gas such as phosphorus trifluoride (PF₃) is used under conditions of low pressure, low source power, high bias power (high ion energy) to chemically modify the side of MTJ layer during plasma main etch and enhance the chemical etch rate of the targeted material. Further chemical etching upon the targeting metal and magnetic material is thus made possible, taking advantage of favorable remote plasma etch characteristics.

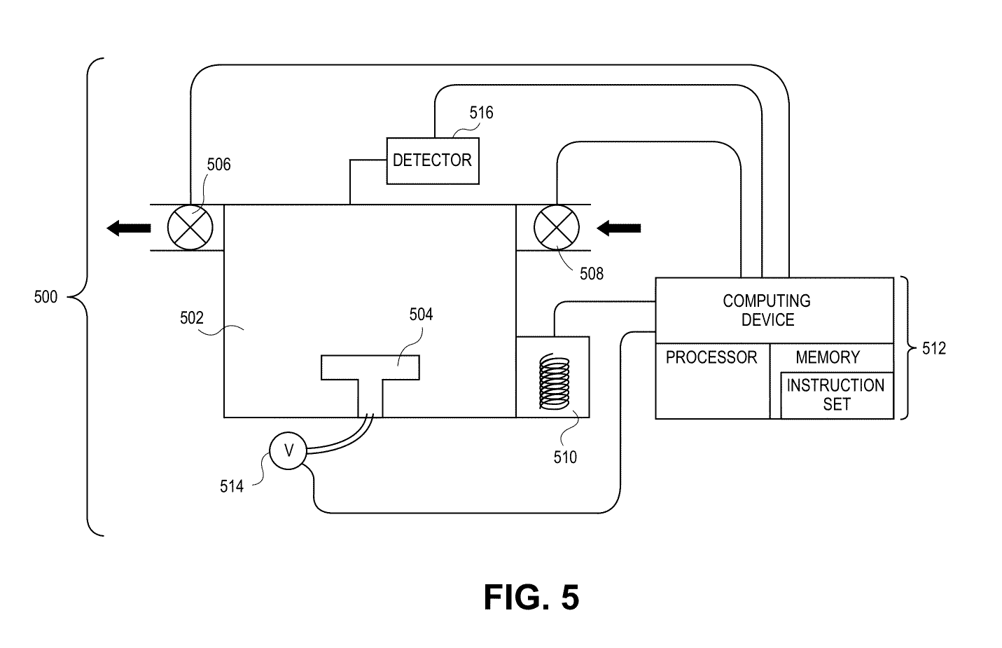

Magnetic tunnel junction (MTJ) film stack etch processing may be conducted in processing equipment suitable to provide an etch plasma in proximity to a sample for etching. For example, FIG. 5 illustrates a system in which a method of MTJ film stack etch processing can be performed, in accordance with an embodiment of the present invention.

Referring to FIG. 5, a system 500 for conducting a plasma etch process includes a chamber 502 equipped with a sample holder 504. An evacuation device 506, a gas inlet device 508 and a plasma ignition device 510 are coupled with chamber 502. A computing device 512 is coupled with plasma ignition device 510. System 500 may additionally include a voltage source 514 coupled with sample holder 904 and a detector 516 coupled with chamber 502. Computing device 512 may also be coupled with evacuation device 506, gas inlet device 508, voltage source 514 and detector 516, as depicted in FIG. 5.

Chamber 502 and sample holder 504 may include a reaction chamber and sample positioning device suitable to contain an ionized gas, i.e. a plasma, and bring a sample in proximity to the ionized gas or charged species ejected there from. Evacuation device 506 may be a device suitable to evacuate and de-pressurize chamber 502. Gas inlet device 508 may be a device suitable to inject a reaction gas into chamber 502. Plasma ignition device 510 may be a device suitable for igniting a plasma derived from the reaction gas injected into chamber 502 by gas inlet device 508. Detection device 516 may be a device suitable to detect an end-point of a processing operation. In one embodiment, system 500 includes a chamber 502, a sample holder 504, an evacuation device 506, a gas inlet device 508, a plasma ignition device 510 and a detector 516 similar to, or the same as, those included in an Applied Centura® Enabler dielectric etch system, an Applied Materials™ AdvantEdge G3 system, or an Applied Materials™ C3 dielectric etch chamber.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

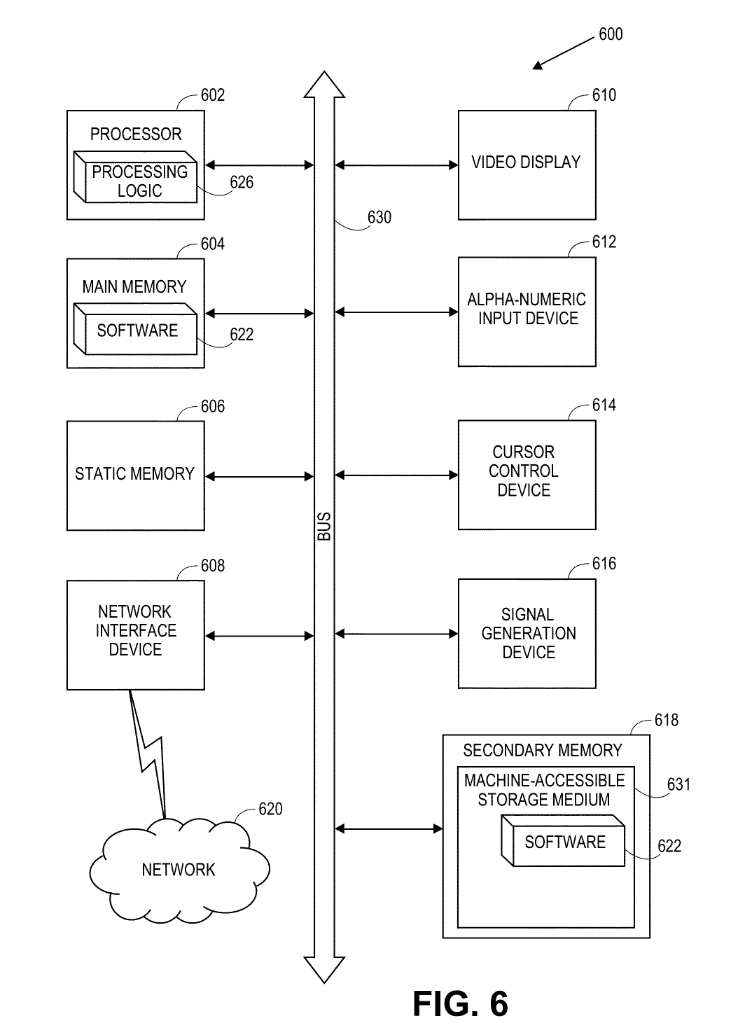

FIG. 6 illustrates a diagrammatic representation of a machine in the exemplary form of a computer system 600 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In one embodiment, computer system 600 is suitable for use as computing device 512 described in association with FIG. 5.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations discussed herein.

The computer system 600 may further include a network interface device 608. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 631 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In accordance with an embodiment of the present invention, a non-transitory machine-accessible storage medium has instructions stored thereon which cause a data processing system to perform a method of etching a magnetic tunnel junction (MTJ) film stack. The method includes modifying one or more layers of the MTJ film stack with a phosphorous trifluoride (PF₃) source to provide modified regions of the MTJ film stack. The modified regions of the MTJ film stack are removed by a plasma etch process.

Thus, chemical modification of non-volatile magnetic random access memory (MRAM) magnetic tunnel junctions (MTJs) for film stack etching has been disclosed.

What is claimed is:

1. A method of etching a magnetic tunnel junction (MTJ) film stack, the method comprising:
modifying one or more layers of the MTJ film stack with a phosphorous trifluoride (PF₃) source to provide modified regions of the MTJ film stack; and
removing the modified regions of the MTJ film stack by a plasma etch process.

2. The method of claim 1, wherein the MTJ film stack includes a CoPt or CoPd layer, and removing the modified regions of the MTJ film stack by the plasma etch process comprises removing a modified CoPt or CoPd layer.

3. The method of claim 1, wherein modifying the one or more layers of the MTJ film stack with the PF₃ source comprises:
introducing PF₃ gas into a processing chamber; and
dissociating the PF₃ gas with RF energy in the processing chamber.

4. The method of claim 3, dissociating the PF₃ gas with RF energy comprises forming a fluorine active species for surface etching a ferromagnetic layer of the MTJ film stack, and forming a phosphorous active species for incorporation into the ferromagnetic layer of the MTJ film stack.

5. The method of claim 1, wherein modifying the one or more layers of the MTJ film stack with the PF₃ source comprises using a plasma immersion process.

6. The method of claim 5, wherein using the plasma immersion process comprises using a shadow ring to shield a portion of a substrate having the MTJ film stack thereon.

7. The method of claim 1, wherein removing the modified regions of the MTJ film stack by the plasma etch process comprises using an oxygen (O₂) based plasma process.

8. The method of claim 7, further comprising:
subsequent using the O₂ based plasma process, cleaning the MTJ film stack with a chemical etch or dry clean process.

9. A method of etching a magnetic tunnel junction (MTJ) film stack, the method comprising:
providing a substrate having the MTJ film stack disposed thereon;
modifying one or more layers of the MTJ film stack with a phosphorous trifluoride (PF₃) source to provide modified regions of the MTJ film stack, the modifying comprising:
introducing PF₃ gas into a processing chamber; and
dissociating the PF₃ gas with RF energy in the processing chamber;
removing the modified regions of the MTJ film stack by a plasma etch process, the removing comprising using an oxygen (O₂) based plasma process; and
subsequent using the O₂ based plasma process, cleaning the MTJ film stack with a chemical etch or dry clean process.

10. The method of claim 9, wherein the MTJ film stack includes a CoPt or CoPd layer, and removing the modified regions of the MTJ film stack by the plasma etch process comprises removing a modified CoPt or CoPd layer.

11. The method of claim 9, wherein dissociating the PF₃ gas with RF energy comprises forming a fluorine active species for surface etching a ferromagnetic layer of the MTJ film stack, and forming a phosphorous active species for incorporation into the ferromagnetic layer of the MTJ film stack.

12. The method of claim 9, wherein modifying the one or more layers of the MTJ film stack with the PF₃ source comprises using a plasma immersion process, the plasma immersion process comprising using a shadow ring to shield a portion of the substrate having the MTJ film stack thereon.

13. A non-transitory machine-accessible storage medium having instructions stored thereon which cause a data processing system to perform a method of etching a magnetic tunnel junction (MTJ) film stack, the method comprising:
modifying one or more layers of the MTJ film stack with a phosphorous trifluoride (PF₃) source to provide modified regions of the MTJ film stack; and
removing the modified regions of the MTJ film stack by a plasma etch process.

14. The non-transitory machine-accessible storage medium of claim 13, wherein the MTJ film stack includes a CoPt or CoPd layer, and removing the modified regions of the MTJ film stack by the plasma etch process comprises removing a modified CoPt or CoPd layer.

15. The non-transitory machine-accessible storage medium of claim 13, wherein modifying the one or more layers of the MTJ film stack with the PF₃ source comprises:
introducing PF₃ gas into a processing chamber; and
dissociating the PF₃ gas with RF energy in the processing chamber.

16. The non-transitory machine-accessible storage medium of claim 15, dissociating the PF₃ gas with RF energy comprises forming a fluorine active species for surface etching a ferromagnetic layer of the MTJ film stack, and forming a phosphorous active species for incorporation into the ferromagnetic layer of the MTJ film stack.

17. The non-transitory machine-accessible storage medium of claim 13, wherein modifying the one or more layers of the MTJ film stack with the PF₃ source comprises using a plasma immersion process.

18. The non-transitory machine-accessible storage medium of claim 17, wherein using the plasma immersion process comprises using a shadow ring to shield a portion of a substrate having the MTJ film stack thereon.

19. The non-transitory machine-accessible storage medium of claim 13, wherein removing the modified regions of the MTJ film stack by the plasma etch process comprises using an oxygen (O₂) based plasma process.

20. The non-transitory machine-accessible storage medium of claim 19, further comprising:
subsequent using the O₂ based plasma process, cleaning the MTJ film stack with a chemical etch or dry clean process.
